(19) United States
(12) Patent Application Publication
(10) Pub. No.: US 2011/0023781 A1
(43) Pub. Date: Feb. 3, 2011

(54) DEVICE FOR THE PLASMA TREATMENT OF WORKPIECES

(76) Inventors: Sönke Siebels, Hamburg (DE); Sebastian Kytzia, Hamburg (DE); Hartwig Müller, Lutjensee (DE); Felix Tietz, Hamburg (DE)

Correspondence Address: LUCAS & MERCANTI, LLP, 475 PARK AVENUE SOUTH, 15TH FLOOR, NEW YORK, NY, 10016, US

(21) Appl. No.: 12/679,291

(22) PCT Filed: Aug. 14, 2008
(86) PCT No.: PCT/DE2008/001351

§ 371 Date: Oct. 22, 2010

(30) Foreign Application Priority Data
Sep. 21, 2007 (DE) 102007045216.2

(51) Int. Cl. C23C 16/44

(52) U.S. Cl. 118/723 R

(57) ABSTRACT

The device serves for the plasma treatment of workpieces. The workpiece is placed in the chamber of a treatment station which can at least partially be evacuated. The plasma chamber is defined by a chamber bottom, a chamber cover, as well as a lateral chamber wall, and has a positionable gas lance. The gas lance is constructed at least partially of a dielectric.

The invention relates to a device for the plasma treatment of workpieces which have at least one plasma chamber which can be evacuated and which serves for receiving the workpieces, wherein the plasma chamber is arranged in the area of a treatment station, wherein the plasma chamber is defined by a chamber bottom, a chamber cover, and a lateral chamber wall, and wherein the plasma chamber has one positionable gas lance.

Devices of this type are used, for example, for providing synthetic materials with surface coatings. In particular, devices are already known for coating the inner or outer surfaces of containers which are intended for packaging liquids. Moreover, devices for plasma sterilization are known.

PCT-WO 95/22413 describes a plasma chamber for the internal coating of bottles. The bottles to be coated are lifted through a movable bottom into a plasma chamber and are connected to an adaptor in the area of a bottle opening. An evacuation of the bottle interior can be effected through the adaptor. Moreover, a hollow gas lance is inserted into the inner space of the bottle through the adaptor, so that processed gas can be conducted into the interior. An ignition of the plasma takes place with the use of a microwave.

This publication also already mentions arranging a plurality of plasma chambers on a rotating wheel. This reinforces a high production rate of bottles per unit of time.

EP-OS 1010773 explains a feeding device for evacuating a bottle interior and to supply it with processed gas. PCT-WO 01/31680 describes a plasma chamber in which the bottles are introduced by a movable cover which previously had been connected to an area of the opening of the bottle.

PCT-WO 00/58631 also shows the arrangement of plasma stations on a rotating wheel and describes for such an arrangement an assignment of vacuum pumps and plasma stations in groups in order to support a favorable evacuation of the chambers and of the interiors of the bottles. Moreover, the coating of several containers in a common plasma station or a common cavity is mentioned.

Another arrangement for carrying out an internal coating of bottles is described in PCT WO 99/17334. Described in particular in this instance is an arrangement of a microwave generator above the plasma chamber, as well as a vacuum and an operating media supply line through a bottom of the plasma chamber.

DE 10 2004 020 185 A1 already describes a gas lance which can be moved into the interior of a preform to be coated and serves for supplying processed gases. The gas lance is positionable in the longitudinal direction of the container.

In the predominant number of the known devices container layers produced by the plasma from silicon oxides having the general chemical formula SiOx are used for improving the barrier properties of the thermoplastic material. Such barrier layers prevent a penetration of oxygen into the packaged liquids and a leakage of carbon dioxide in CO₂ containers containing liquids.

The devices which have become known so far are not yet suitable to a sufficient extent for use in a mass production in which a low coating price per workpiece has to be achieved as well as a high production speed.

In particular, there is the problem that the microwaves enter the interior of the gas lance as well as spread into an angular gap which surrounds the gas lance in the area of the valve block which is arranged adjacent the coating chamber. Since processed gases can be found in the interior of the gas lance as well as the area of the valve block, the penetrating microwaves lead to an ignition of the plasma also in this area and to coating defects. These undesirable coatings reduce the available flow cross-sections, and moreover the mobility of the respected structural element is impaired. With respect to the valves in the area of the valve block, after a certain time of operation it can no longer be ensured that the valves are closed tightly, so that maintenance cycles and cleaning work become frequently necessary.

It is the object of the present invention to improve a device of the above-described type in such a way that an operation with little trouble and reduced maintenance is achieved.

In accordance with the invention, this object is met by constructing the gas lance at least over portions thereof so as to be dielectric.

In accordance with the invention, it has been found that metal tube-like gas lances which are used in the prior art favor the undesired spreading of the microwaves into the interior of the bottle supports and into the area of the valve block. By using the dielectric gas lance, a corresponding spreading out of the microwaves is prevented. Moreover, it has been found that the use of the dielectric gas lance reinforces an adaptation of the coating process to different bottle geometries and different product requirements. The gas lance protrudes to different distances into the container to be coated in dependence on the concrete coating requirements. In this connection, a metal gas lance influences the spreading of the microwaves, so that, in the prior art, an adaptation of the generation of microwaves is necessary in dependence on the respective positioning of the gas lance. When dielectric gas lances are used, it has been found that independently of the concrete position of the gas lance, no significant influences of the spreading of the microwave occur, so that the process is significantly easier to control.

A high mechanical stability with a simultaneous screening made available relative to microwaves, is achieved by constructing the gas lance at least over portions thereof on the outer side of dielectrics.

An inexpensive construction is supported by constructing the gas lance as a tube and constructing at least over the entire thickness of the tube wall of the dielectric.

A change of resonant properties in dependence on a positioning on the gas lance can be avoided by constructing the gas lance at least in an area which protrudes into the plasma chamber of the dielectric.

The microwaves are prevented from emerging from the area of the plasma chamber by constructing the gas lances of the dielectric material at least in that area of a support element which positions the workpiece and faces toward the plasma chamber.

Undesired coatings in the area of a chamber base can be prevented by constructing the gas lance at least in a portion thereof of the dielectric material which is surrounded by an area of the chamber base which faces the plasma chamber.

To prevent undesired coatings of valves or vacuum ducts, it is proposed that the gas lance is constructed at least in a portion thereof of the dielectric material which is surrounded by a valve block and faces the plasma chamber.

A construction which can be manufactured particularly easily by making the gas lance completely of the dielectrical material.

A combination of different material properties is achieved by constructing the gas lance of at least two different dielectrical materials which are arranged one above the other in the radial direction. Moreover, it is also being considered that the gas lance be manufactured of at least two dielectric materials which are arranged one above the other in the longitudinal direction.

Advantageous dielectric properties are made available by making the dielectric at least partially of carbon.

A high mechanical stability is also achieved if the dielectric material is at least partially of carbon fibers.

A ware of the gas lance due to processed gases acting on the lance can be reduced significantly if the dielectric material is at least partially of ceramic material.

An inexpensive construction of the gas lance is achieved if the dielectric material is at least partially of synthetic material.

Embodiments of the invention are schematically illustrated in the drawing.

In the drawing:

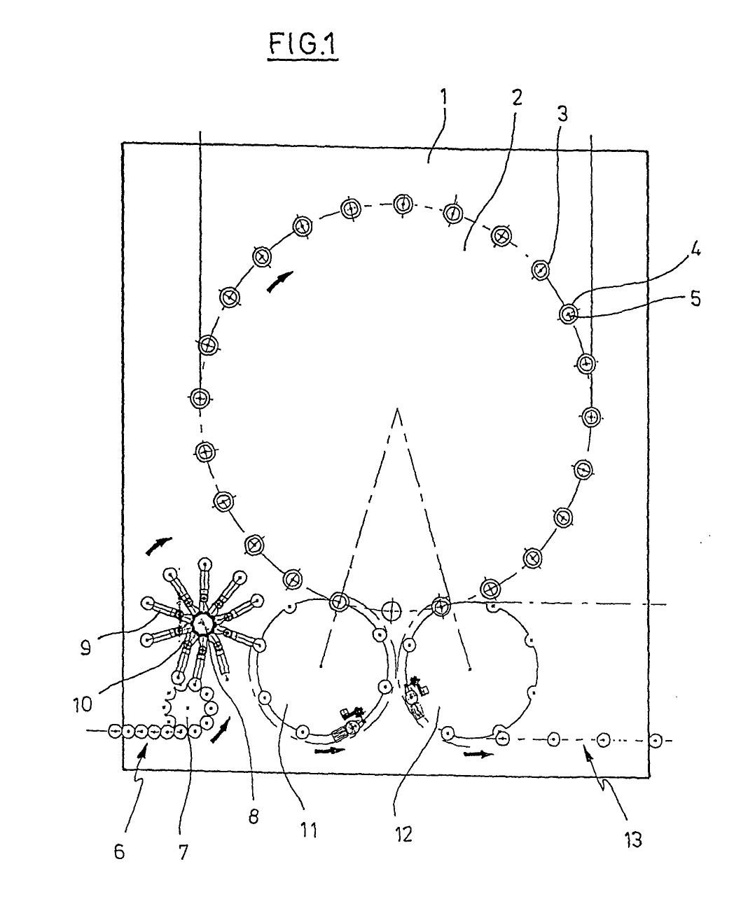

FIG. 1 shows an illustration of a plurality of plasma chambers arranged on a rotating plasma wheel, wherein the plasma wheel is coupled to feeding and discharging wheels;

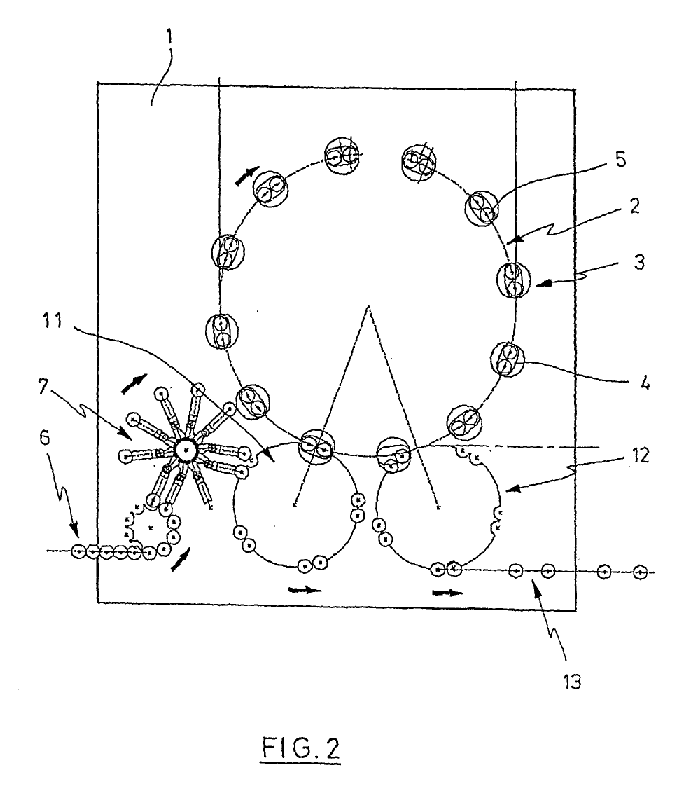

FIG. 2 shows an arrangement, similar to FIG. 1, in which the plasma stations each have two plasma chambers;

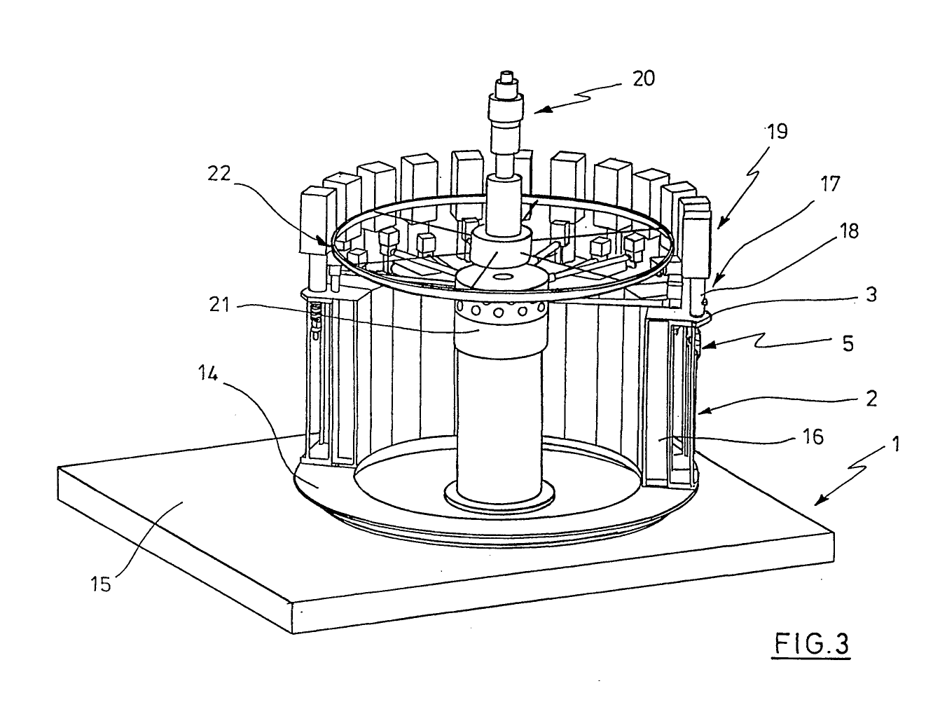

FIG. 3 is a perspective view of a plasma wheel with a plurality of plasma chambers;

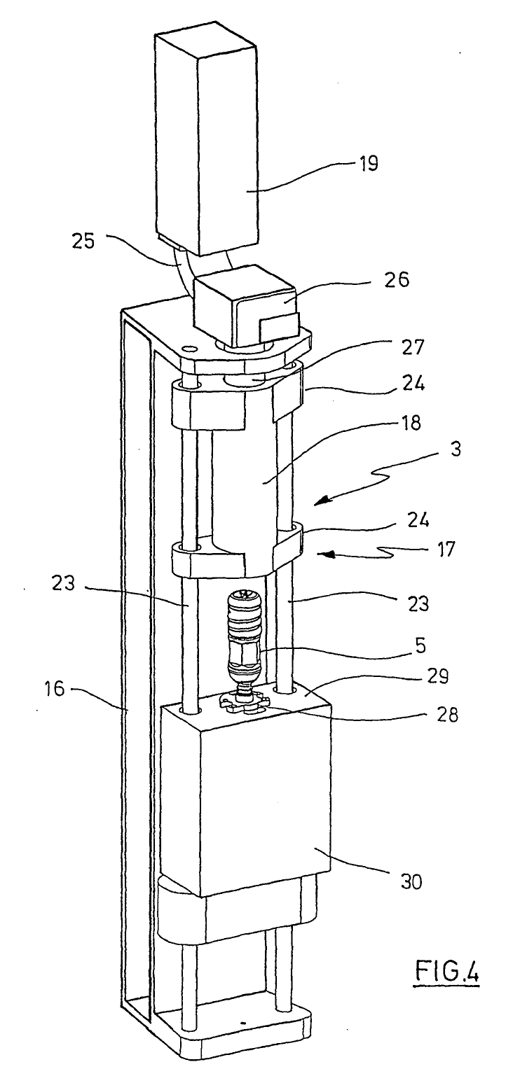

FIG. 4 is a perspective illustration of a plasma station with a cavity;

FIG. 5 is a front view of the device of FIG. 4 with the plasma chamber being closed;

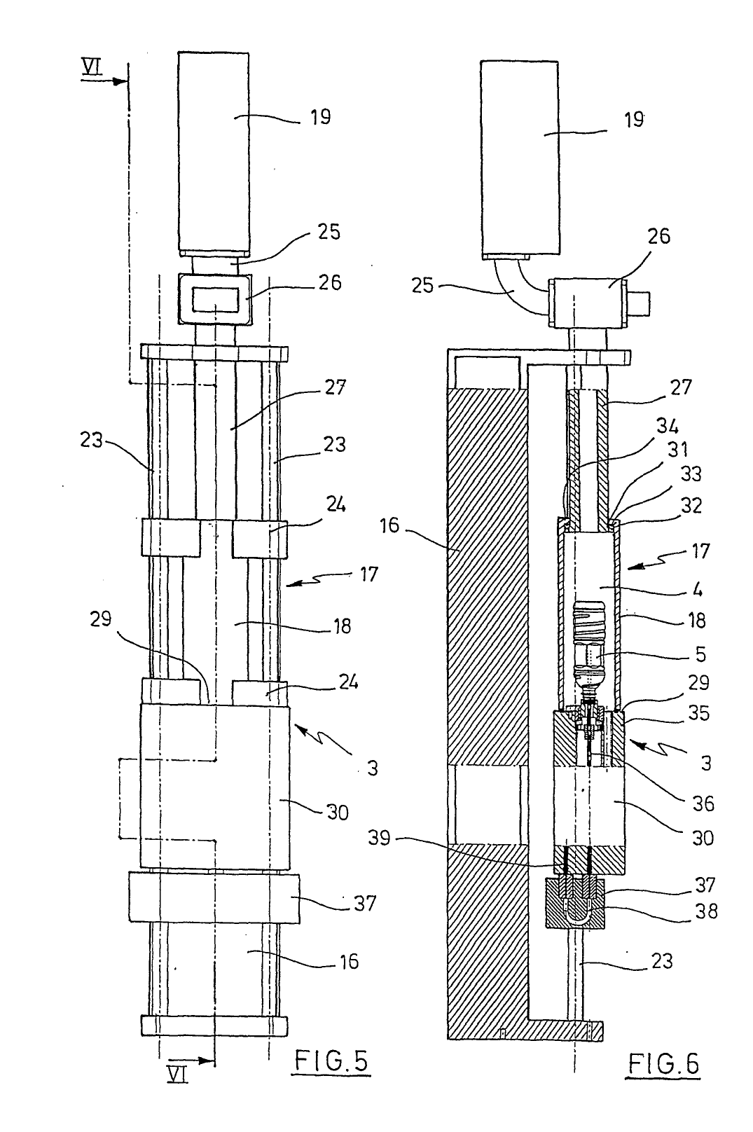

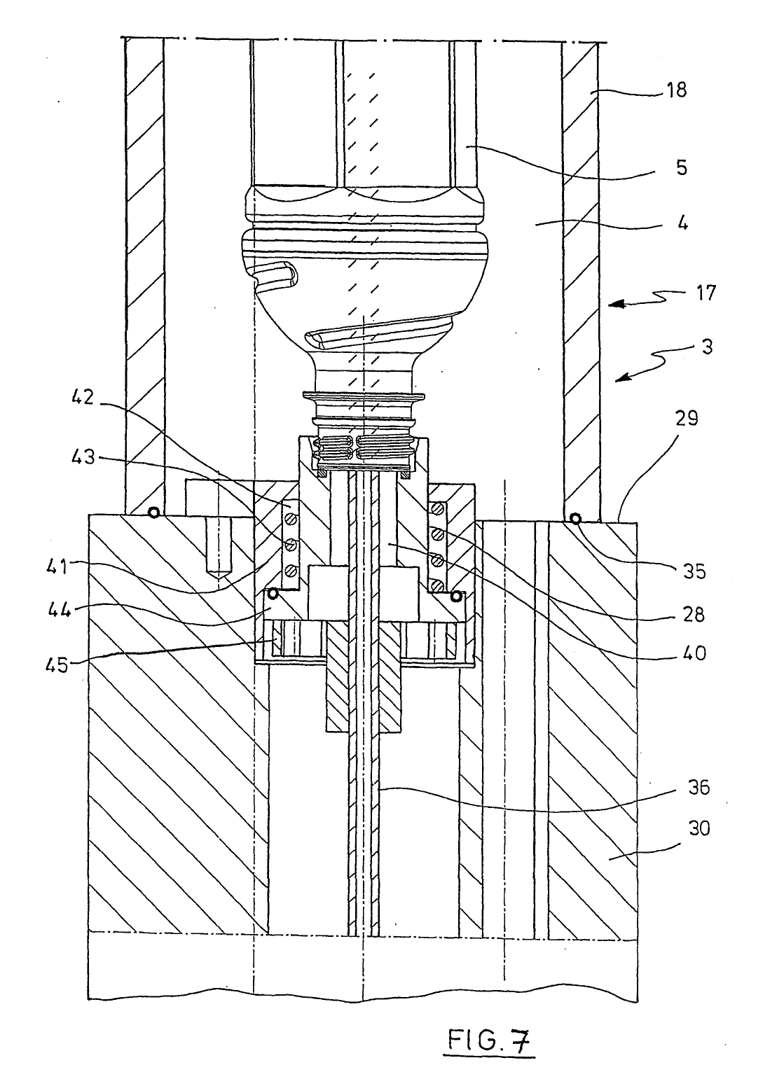

FIG. 6 is a cross-sectional view taken along sectional line IV in FIG. 5; and

FIG. 7 is an enlarged sectional view of a connecting element for supporting the workpiece in the plasma chamber and a gas lance insertable into the workpiece.

From the illustration in FIG. 1 can be seen a plasma module 1 which is provided with a rotating plasma wheel 2. Along a circumference of the plasma wheel 2, a plurality of plasma stations 3 are arranged. The plasma stations 3 are provided with cavities 4 for plasma chambers 17 for receiving workpieces 5 to be treated.

The workpieces 5 to be treated are supplied to plasma module 1 in the area of an input 6 and are conducted over a separating wheel 7 to a transfer wheel 8 which is equipped with positionable support arms 9. The support arms 9 are arranged relative to a base 10 of the transfer wheel 8 so as to be pivotable, so that a distance change of the workpieces 5 relative to each other can be carried out. This results in a transfer of the workpieces 5 from the transfer wheel 8 to an input wheel 11 with an increased distance of the workpieces 5 relative to each other and relative to the separating wheel 7. The input wheel 11 transfers the workpieces 5 to be treated to the plasma wheel 2. After the treatment has been carried out, the treated workpieces 5 are removed by an output wheel 12 from the area of the plasma wheel 2 and into the area of an output section 13.

In the embodiment according to FIG. 2, the plasma stations 3 are each equipped with two cavities 4 or plasma chambers 17. As a result, always two workpieces 5 can be treated simultaneously. It is basically possible in this connection to construct the cavities 4 completely separate from each other, however, it is basically also possible to arrange in a common cavity chamber only partial areas in such a way that an optimum coating of all workpieces 5 is ensured. It is particularly intended to separate the partial cavities at least by separate microwave couplings relative to each other.

FIG. 3 shows a perspective illustration of a plasma module 1 with partially built-up plasma wheel 2. The plasma stations 3 are arranged on a support ring 14 which is formed as a part of a rotary connection and is supported in the area of a machine base 15. The plasma stations 3 each have station frames 16 for supporting the plasma chambers 17. The plasma chambers 17 have cylindrical chamber walls 18 and microwave generators 19. In a center of the plasma wheel 2, a rotary distributor 20 is arranged through which the plasma stations 3 can be supplied with operating means and energy, in particular, angular lines 21 can be used for distributing the operating means. The workpieces to be treated are illustrated underneath the cylindrical chamber walls 18. Lower portions of the plasma chamber 17 are not illustrated for simplification.

FIG. 4 shows a plasma station 3 in a perspective illustration. It can be seen that the station frame 16 is provided with guide rods 23 on which is guided a carriage 24 for supporting the cylindrical chamber wall 18. FIG. 4 shows the carriage 4 with chamber wall 18 in a raised state, so that the workpiece 5 is released.

In the upper range of the plasma station 3 is arranged the microwave generator 19. The microwave generator 19 is connected through a deflection 25 and an adaptor 26 to a coupling channel 27 which leads into the plasma chamber 17. The microwave generator 19 may basically be coupled directly in the area of the chamber cover 31 as well as through a spacer element to the chamber cover 31 with a predeterminable distance from the chamber cover 31, and, thus, in a larger surrounding area of the chamber cover 31. The adaptor 26 has the function of a transfer element and the coupling duct 27 is constructed as a coaxial conductor. In the area where the coupling duct 27 leads into the chamber cover 31, a quartz glass window is arranged. The deflection 25 is constructed as a hollow conductor.

The workpiece 5 is positioned by a support element 28 which is arranged in the area of a chamber bottom 29. The chamber bottom 29 is constructed as a part of a chamber base 30. To facilitate its adjustment, it is possible to secure the chamber base 30 in the area of the guide rods 20. In accordance with another embodiment, the chamber base 30 is fastened directly to the station frame 16. In such an arrangement, it is, for example, also possible to construct the guide rods 3 in two parts in the vertical direction.

FIG. 5 shows a front view of a plasma station according to FIG. 3 in a closed state of the plasma chamber 17. The carriage 24 is in this case lowered with the cylindrical chamber 18 relative to the position in FIG. 4 so that the chamber wall 18 is moved against the chamber bottom 29. In this state of position, the plasma coating can be carried out.

FIG. 6 shows in a vertical sectional view the arrangement according to FIG. 5. It is particularly possible to see that the coupling duct 27 leads into a chamber cover 31 that is provided with a laterally protruding flange 32. A seal 33 is arranged in the area of the flange 32, wherein an internal flange 34 of the chamber wall 18 acts on the seal 33. In a lowered state of the chamber wall 18, this results in a sealing action of the chamber wall relative to the chamber cover 1. Another seal 35 is arranged in a lower area of the chamber wall 18, so that a sealing action relative to the chamber bottom 29 is also ensured in this case.

In the position illustrated in FIG. 6, the wall 18 surrounds the cavity 4 so that an inner space of the cavity 4 as well as an inner space of the workpiece 5 can be evacuated. For supporting the supply of processed gas, a hollow gas lance 36 is arranged in the area of the chamber base 30 which is movable into the interior of the workpiece 5. For carrying out a positioning of the gas lance 36, the gas lance is supported by a lance carriage 37 which can be positioned along the guide rods 23. A processed gas duct 38 extends within the lance carriage 37, wherein the processed gas duct 38 is in the raised position illustrated in FIG. 6 coupled to a gas connection 39 of the chamber base 30. As a result of this arrangement, hose-like connecting elements at the lance carriage 37 are avoided.

In the position illustrated in FIG. 7, a push plate 45 mounted at the gas lance 36 is guided against the outer flange and presses the support element 28 into its upper end position. In this position, an interior space of workpiece 5 is isolated from the interior of the cavity 4. In a lowered state of the lance 36, the compression spring 43 displaces the support element 28 relative to the guide sleeve 41 in such a way that a connection is provided between the interior of workpiece 5 and the interior of cavity 4.

As an alternative to the above-explained construction of the plasma station, it is according to the present invention also possible to introduce the workpiece 5 into a plasma chamber 17 which is immovable relative to the immovable plastic chamber 17. Moreover, it is possible, as an alternative to the illustrated coating of the workpieces 5 with their openings extending upwardly in the vertical direction. In particular, it is intended to carry out a coating of bottle-shaped workpieces 5. Such bottles are preferably also constructed of a thermoplastic material. Preferably, the use of PET or PP is conceivable. In accordance with another embodiment, the coated bottles serve to receive beverages.

A typical treatment process is in the following explained with the aid of a coating process. The process is carried out in such a way that initially the workpiece 5 is with the use of an input wheel 11 transported to the plasma wheel 2 and in a raised position of the sleeve-like chamber wall 18, the insertion of the workpiece 5 into the plasma station 3 takes place. After the insertion process has been concluded, the chamber wall 18 is lowered into its sealed position and initially a simultaneous evacuation of the cavity 4 as well as the interior space of the workpiece 5 is carried out.

After a sufficient evacuation of the interior of the cavity 4, the lance 36 is inserted into the interior of the workpiece 5 and the interior of the workpiece 5 is sealed off relative to the interior of the cavity 4. It is also possible to move the gas lance 36 already synchronously with the beginning evacuation of the interior of the cavity into the workpiece 5. The pressure in the interior of the workpiece 5 is then lowered even further. Moreover, it is also conceivable to carry out the positioning movement of the gas lance 36 at least partially parallel to the positioning of the chamber wall 18. After a sufficiently low negative pressure has been reached, the processed gas is introduced into the interior of the workpiece 5 and the plasma is ignited by means of the microwave generator 19. It is particularly conceivable to separate by means of the plasma a bonding agent to an interior surface of the workpiece 5 as well as the actual barrier layer of silicon oxide.

After the coating process has been concluded, the gas lance 36 is once again removed form the interior of the workpiece 5 and the plasma chamber 17 as well as the workpiece 5 are ventilated. After reaching the ambient pressure within the cavity 4, another chamber wall 18 is raised again and the coated workpiece 5 is removed and a new workpiece to be coated is inserted.

Positioning of the wall 18, of the sealing element 28 and/or the gas lance 36 can take place with the use of different drive units. Basically, the use of pneumatic drives and/or electric drives, especially in an embodiment as a linear motor, are conceivable. However, in particular it is intended, for reinforcing an exact movement coordination, to realize a cam control with a rotation of the plasma wheel 2. The cam control can be constructed, for example, in such a way that control cams are arranged alongside a circumference of the plasma wheel 2 along which the cam rollers are guided. The cam rollers are coupled to the structural elements which are to be positioned.

With respect to the material for the gas lance 36, the portion of the gas lance 36 extending into the plasma chamber 17 is at least partially constructed of a dielectric. In particular, it is intended that the area arranged within the plasma chamber 17, as well as the part of the support element 28 facing the plasma chamber 17 are constructed of the dielectric. With respect to manufacturing technology, it has been found particularly advantageous to construct the entire gas lance 36 of the dielectric material. As a result, inexpensive tubular elements can be used which are divided as needed into the required gas lances 36. For example, it is possible to construct such tubes of plastic materials and to extrude them.

The use of plastic materials which are cut as needed, makes it possible to omit time consuming cleaning processes of the gas lance 36 and to replace a contaminated gas lance 36 by a new gas lance 36. This makes it possible to significantly reduce necessary service times, so that economic advantages can be achieved if prefabricated gas lances 36 are used that have a low material price.

1. Device for plasma treatment of workpieces, comprising at least one plasma chamber to be evacuated for receiving the workpiece, wherein the plasma chamber is arranged in the area of the treatment station, and wherein the chamber wall is defined by a chamber bottom, a chamber cover, as well as a lateral chamber wall, and a positionable gas lance, wherein the gas lance (36) is constructed at least over portions thereof of a dielectric.

2. The device according to claim 1, wherein the gas lance (36) is constructed of the dielectric at least over portions of the outer side.

3. The device according to claim 1, wherein the gas lance (36) constructed tubular and is constructed at least over portions thereof with the total thickness of the tube wall of the dielectric.

4. The device according to claim 1, wherein the gas lance (36) is constructed of the dielectric at least in an area protruding into the plasma chamber (17).

5. The device according to claim 1, wherein the gas lance (36) is constructed at least in its area of the dielectric, wherein the area facing the plasma chamber is surrounded by holding element (28) which surrounds the workpiece.

6. The device according to claim 1, wherein the gas lance (36) is at least in a portion constructed of the dielectric, wherein the gas lance (36) is constructed of the dielectric at least in an area which is surrounded by an area of a chamber base (30) facing the plasma chamber.

7. The device according to claim 1, wherein the gas lance (36) is at least in a portion constructed of the dielectric, wherein the gas lance (36) is constructed of the dielectric at least in an area which is surrounded by an area of a valve block facing the plasma chamber.

8. The device according to claim 1, wherein the gas lance (36) is entirely constructed of the dielectric.

9. The device according to claim 1, wherein the gas lance (36) is constructed of at least two different dielectrics that are arranged in a radial direction one above the other.

10. The device according to claim 1, wherein the gas lance (36) is constructed over at least two different dielectrics which are arranged one above the other in a longitudinal direction.

11. The device according to claim 1, wherein the dielectric is composed at least partially of carbon.

12. The device according to claim 1, wherein the dielectric is comprised at least partially of carbon fibers.

13. The device according to claim 1, wherein the dielectric is composed at least partially of ceramic material.

14. The device according to claim 1, wherein the dielectric is comprised at least partially of synthetic material.
